(19) United States
(12) Patent Application Publication
(10) Pub. No.: US 2026/0173422 A1
(43) Pub. Date: Jun. 18, 2026

(54) STRUCTURES AND METHODS FOR FORMING STRUCTURES WITH INNER SPACERS

(71) Applicant: Taiwan Semiconductor Manufacturing Company, Ltd., Hsinchu (TW)

(72) Inventors: Chen-Huang Huang, Hsinchu (TW); Li-Wei Yin, Hsinchu City (TW); Kuo-Chin Liu, Ji-an Township (TW); Ryan Chia-Jen Chen, Hsinchu (TW)

(73) Assignee: Taiwan Semiconductor Manufacturing Company, Ltd., Hsinchu (TW)

(21) Appl. No.: 18/980,423

(22) Filed: Dec. 13, 2024

(51) Int. Cl. H10D 30/01; H10D 84/83

(52) U.S. Cl. CPC H10D 30/0195; H10D 84/83138; H10D 84/832

(57) ABSTRACT

Provided are semiconductor structures and methods for fabricating semiconductor structures. A method includes, in a first device region and in a second device region: forming a semiconductor layer over an interposer layer; etching a trench through the semiconductor layer and interposer layer; forming an inner spacer laterally adjacent to the trench; and removing the interposer layer. The method further includes covering the second device region with a mask, and recessing the inner spacer laterally in the first device region.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIGS. 2-6 are perspective views of a structure of the semiconductor device during successive stages of fabrication, in accordance with some embodiments.

FIG. 7 is a cross-sectional view of the structure of the semiconductor device in FIG. 6, in accordance with some embodiments.

FIG. 8 is a perspective view of a structure of the semiconductor device during a successive stage of fabrication, in accordance with some embodiments.

FIG. 9 is a cross-sectional view of the structure of the semiconductor device in FIG. 8, in accordance with some embodiments.

FIGS. 10-15, 17, 19, 21, 23, and 25 are Y-cut cross-sectional views of a portion of structure of the semiconductor device during successive stages of fabrication, in accordance with some embodiments.

FIGS. 16, 18, 20, 22, 24 and 26 are X-cut cross-sectional views of a portion of structure of the semiconductor device at the same stage of fabrication as the proceeding Y-cut view, in accordance with some embodiments.

FIG. 27 is a Y-cut cross-sectional view of a portion of structure of the semiconductor device illustrating various dimensions, in accordance with some embodiments.

FIGS. 28-29 are Y-cut cross-sectional views illustrating interfaces between metal gates and inner spacers in different device regions, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that, when an overlying feature that is directly over an underlying feature, a vertical axis passes through both features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

All numbers in this description indicating amounts, ratios of materials, physical properties of materials, and/or use are to be understood as modified by the word “about,” except as otherwise explicitly indicated. When modifying a numerical value in the specification or claims, “about” denotes an interval of accuracy, familiar and acceptable to a person skilled in the art. In general, such interval of accuracy is ±ten percent. Thus, “about ten” means nine to eleven.

In certain embodiments herein, a “material layer” is a layer that includes at least 50 wt. % of the identified material, for example at least 60 wt. % of the identified material, at least 75 wt. % of the identified material, at least 90 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, or at least 99 wt. % of the identified material. For example, certain embodiments, each of a titanium nitride layer and a layer that is titanium nitride is a layer that is at least 50 wt. %, at least 60 wt. %, at least 75 wt. %, titanium nitride, at least 90 wt. % titanium nitride, or at least 99 wt. % titanium nitride.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Certain embodiments herein are generally related to multi-gate transistors. Multi-gate transistors include those transistors whose gate structures are formed on at least two-sides of a channel region. These multi-gate devices may include a p-type metal-oxide-semiconductor device or an n-type metal-oxide-semiconductor multi-gate device. Specific examples may be presented and referred to herein as gate-all-around (GAA) devices. A GAA device includes any device that has its gate structure, or portion thereof, formed on four sides of a channel region (e.g., surrounding a portion of a channel region).

It is noted that while the Figures and description recite the structure of a gate-all-around (GAA) device, it is contemplated that the methods described herein may be used to fabricate other types of devices, and that the devices described herein may be other types of devices.

Structures presented herein also include embodiments that have channel regions in the form of nanosheets. The term “nanosheet” designates any material portion with nanoscale, or even microscale dimensions, and having an elongated shape, regardless of the cross-sectional shape of this portion. Thus, this term designates both circular and substantially circular cross-section elongated material portions, e.g., nanowires, and beam or bar-shaped material portions including for example a cylindrical or substantially rectangular cross-section.

As described herein, a method is performed to reduce the lateral thickness or critical dimension of inner spacers and to increase the lateral thickness or critical dimension of lower metal gate portions formed between the thinned inner spacers. In certain embodiments, inner spacer thinning operations are performed only on GAA devices in PFET regions and not on GAA devices in NFET regions that are masked. Further, certain embodiments provides structures including GAA devices in PFET regions with lower metal gate portions having relatively greater critical dimensions and including GAA devices in NFET regions with lower metal gate portions having relatively smaller critical dimensions

Certain embodiments herein provide a method for controlling the thickness of inner spacers in adjacent gates during an inner spacer trim process. It has been found that the thickness of the low-K inner spacer and the critical dimension of the metal gate define the electrical performance of the transistor device. Embodiments herein improve DC performance by reducing the thickness of the PFET inner spacer. The thickness of the NFET inner spacer may remain unchanged. Certain embodiments provide for a unique adjacent profile of the metal gate and inner spacer and for differentiated gate metal critical dimensions between PFET and NFET device regions.

Certain embodiments provide a larger process window for wafer acceptance testing control. Certain embodiments provide for a tunable inner metal gate profile to provide improved performance for different devices.

Certain embodiments use a fluoride etch process (NF3, SF6, CF4) with high selectivity to oxide, and then remove low-K inner spacers (SiOCN) to obtain desired gate profiles.

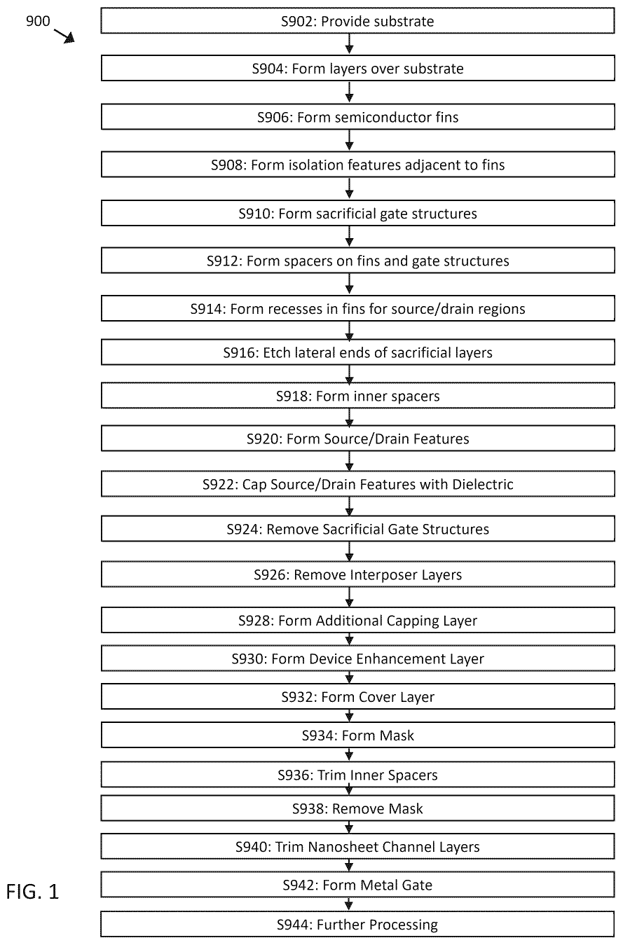

Referring now to FIG. 1, a method 900 for forming a structure, such as a multi-gate device, is illustrated in a flow chart, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as a “nanosheet”.

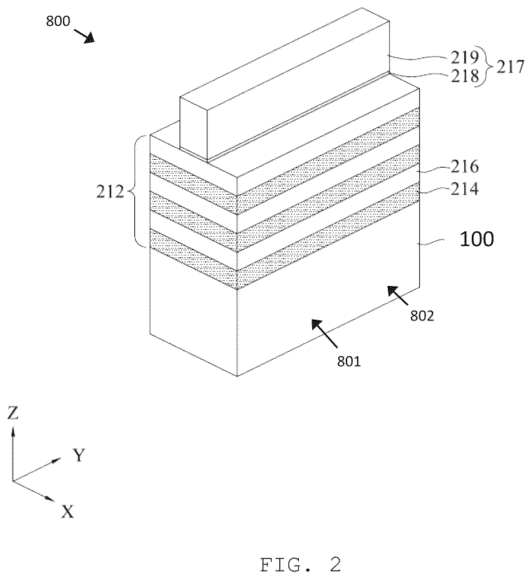

FIG. 1 is described in conjunction with FIGS. 2-26, which illustrate a semiconductor device 800 at various stages of fabrication in accordance with some embodiments of the present disclosure of the method 900. The method 900 is merely an example, and is not intended to limit the present disclosure beyond what is explicitly recited in the claims. Additional steps may be provided before, during, and after method 900, and some of the steps described can be moved, replaced, or eliminated for additional embodiments of method 900. Additional features may be added in the semiconductor device depicted in the Figures and some of the features described below can be replaced, modified, or eliminated in other embodiments of the semiconductor device.

As with other method embodiments and exemplary devices discussed herein, it is understood that parts of the semiconductor device 800 may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the process steps of method 900, including any descriptions given with reference to the Figures, as with the remainder of the method and exemplary figures provided in this disclosure, are merely exemplary and are not intended to be limiting beyond what is specifically recited in the claims that follow.

At operation S902, the method 900 (FIG. 1) provides a substrate 100, as shown in FIG. 2. In some embodiments, the substrate 100 may be a semiconductor substrate such as a silicon (Si) substrate. The substrate 100 may include various layers, including conductive or insulating layers formed on a semiconductor substrate. The substrate 100 may include various doping configurations depending on design requirements as is known in the art. For example, different doping profiles (e.g., p-well, n-well) may be formed on the substrate 100 in regions 801 and 802 designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 100 includes a single crystalline semiconductor layer on at least its surface portion. The substrate 100 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 100 may include a compound semiconductor and/or an alloy semiconductor. In the illustrated embodiment, the substrate 100 is made of crystalline Si.

As shown in FIG. 2, at operation S904, the method 900 (FIG. 1) forms one or more epitaxial layers over the substrate 100. In some embodiments, an epitaxial stack 212 is formed over the substrate 100. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. For example, the epitaxial layers 214 may be referred to as interposers layers 214 that are later selectively removed to define the semiconductor layers 216 as nanosheet channel layers. In an embodiment, the epitaxial layers 214 are SiGe and the epitaxial layers 216 are silicon. In embodiments wherein the epitaxial layer 214 includes SiGe and the epitaxial layer 216 includes silicon, the silicon oxidation rate is less than the SiGe oxidation rate. It is noted that three layers of epitaxial layers 214 and three layers of epitaxial layers 216 are illustrated in FIG. 2, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 800. In some embodiments, the number of epitaxial layers 216 is between two and ten, such as six or seven.

In some embodiments, the epitaxial layer 214 has a thickness ranging from 5 to 15 nm. The epitaxial layers 214 may be substantially uniform in thickness. In some embodiments, the epitaxial layer 216 has a thickness ranging from 5 to 15 nm. In some embodiments, the epitaxial layers 216 of the stack are substantially uniform in thickness. As described in more detail below, the epitaxial layer 216 may serve as channel region(s) for a subsequently formed multi-gate device and has a thickness chosen based on device performance considerations. The epitaxial layer 214 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxial layers 216 include the same material as the substrate 100. In some embodiments, the epitaxially grown layers 214 and 216 include a different material than the substrate 100. As stated above, in at least some examples, the epitaxial layer 214 includes an epitaxially grown Si₁₋ₓGeₓ layer (wherein x is from 0.10 to 0.55 and the epitaxial layer 216 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from 0 cm⁻³ to 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer.

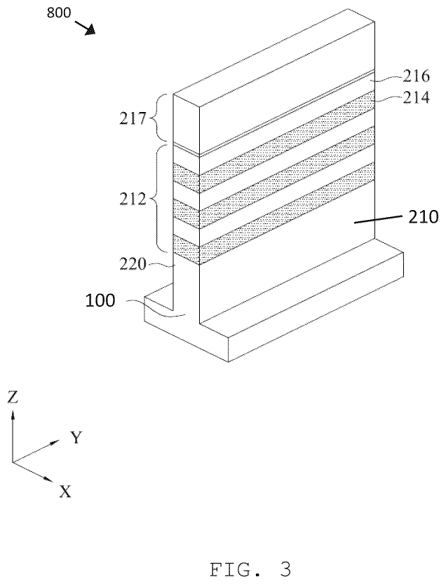

As shown in FIG. 3, at operation S906, the method 900 (FIG. 1) patterns the epitaxial stack 212 to form semiconductor fins 220. In some embodiments, the operation S906 includes forming a mask 217 over the epitaxial stack 212, as shown in FIG. 2. The mask 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask 217 is patterned into a mask pattern by using patterning operations including photolithography and etching.

As shown in FIG. 3, operation S906 subsequently patterns the epitaxial stack 212 in an etching process, such as a dry etch (e.g., reactive ion etching), a wet etch, and/or other suitable process, through openings defined in the patterned mask 217. The stacked epitaxial layers 214 and 216 are thereby patterned into the fin 220. While FIG. 3 illustrates the formation of one fin 220, any suitable number of fins may be formed. Trenches are etched between adjacent fins 220.

In various embodiments, each fin 220 includes an upper portion of the interleaved epitaxial layers 214 and 216, and a bottom portion, or mesa portion 210, that is formed from the etched substrate 100. Each fin 220 protrudes upwardly in the Z-direction from the substrate 100 and extends lengthwise in the Y-direction. Sidewalls of each fin 220 may be vertical or inclined (not shown). In FIG. 3, additional fins would be spaced apart along the X-direction. The fins 220 may have a same width or different widths.

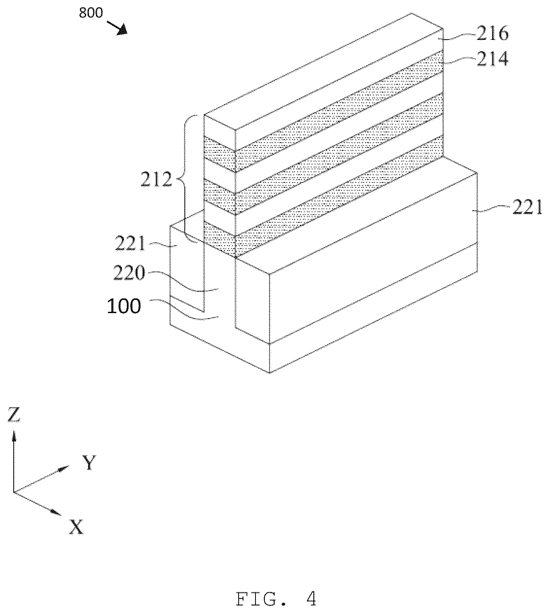

As shown in FIG. 4, at operation S908, the method 900 (FIG. 1) forms isolation features (also denoted as shallow trench isolation or STI features) 221 with a dielectric layer in trenches adjacent to each fin 220. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask 217 are revealed, and the dielectric material layer is recessed to form the shallow trench isolation (STI) features (also denoted as STI features) 221, as shown in FIG. 4. In the illustrated embodiment, the STI features 221 are formed on the substrate 100. Any suitable etching technique may be used to recess the isolation features 221 including dry etching, wet etching, RIE, and/or other etching methods, and in an exemplary embodiment, an anisotropic dry etching is used to selectively remove the dielectric material of the isolation features 221 without etching the fin 220. The mask 217 (shown in FIG. 3) may also be removed before, during, and/or after the recessing of the isolation features 221. In some embodiments, the mask 217 is removed by the CMP process performed prior to the recessing of the isolation features 221. In some embodiments, the mask 217 is removed by an etchant used to recess the isolation features 221.

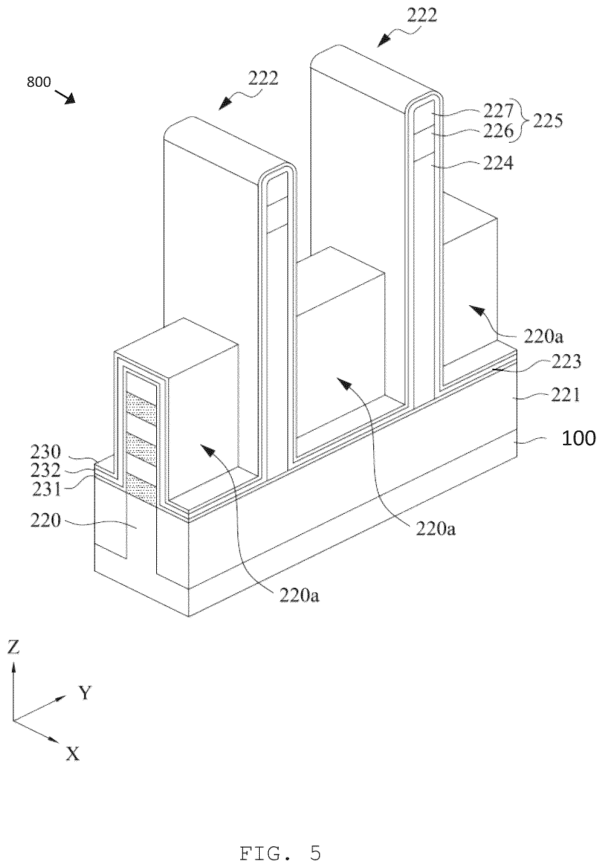

As shown in FIG. 5, at operation S910, the method 900 (FIG. 1) forms sacrificial (dummy) gate structures 222. The sacrificial gate structures 222 are formed over portions of the fin 220 which are to be channel regions. Specifically, the sacrificial gate structures 222 lie directly over and define the channel regions of the GAA devices to be formed. The sacrificial gate structures 222 may extend over a number of adjacent fins (not shown). Each of the sacrificial gate structures 222 includes a sacrificial gate dielectric 223 and a sacrificial gate electrode 224 over the sacrificial gate dielectric 223. As shown, the gate structures 222 extend lengthwise in the X-direction and are spaced apart in the Y-direction.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from 100 to 200 nm in some embodiments. The sacrificial gate electrode layer 224 includes silicon such as polycrystalline silicon or amorphous silicon. The thickness of the sacrificial gate dielectric layer is in a range from 1 to 5 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask 225 is formed over the sacrificial gate electrode layer. The mask 225 may include a mask layer 226 such as silicon oxide and a mask layer 227 such as silicon nitride. Subsequently, a patterning operation is performed on the mask 225, the sacrificial gate electrode layers and the sacrificial gate dielectric layer are patterned into the sacrificial gate structures 222, including sacrificial gate dielectric layer 223 and sacrificial gate electrode 224.

As shown, the fin 220 is partially exposed, i.e., not covered by an overlying structure, between and on opposite sides of the sacrificial gate structures 222, thereby defining source/drain (S/D) regions. As used herein, “source/drain region(s)” or “source/drain feature(s)” may refer to a source or a drain, individually or collectively dependent upon the context.

Still referring to FIG. 5, at operation S912, the method 900 (FIG. 1) forms spacers 230 on sidewalls of the sacrificial gate structures 222 and sidewalls of the fins 220 by depositing spacer materials and then etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 include multiple layers, such as a liner layer 231 and a main spacer layer 232 over the liner layer 231.

By way of example, the spacers 230 may be formed by depositing spacer material including a liner material layer and a dielectric material layer over the sacrificial gate structures 222 using processes such as a subatmospheric CVD (SACVD) process, a flowable CVD process, an ALD process, a PVD process, or other suitable process respectively.

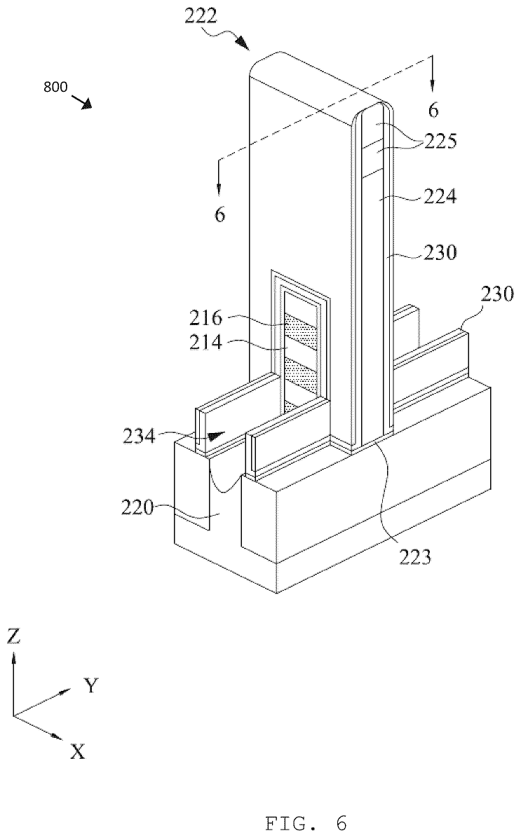

As shown in FIGS. 6 and 7, the deposition of the liner material layer and the dielectric material layer are followed by, at operation S914, an etching-back (e.g., anisotropic) process to expose, and remove, portions 220a of the fins 220 adjacent to and not covered by the sacrificial gate structure 222 (e.g., source/drain regions). Specifically, the method 900 (FIG. 1) recesses the portions of the fin 220 not covered by the sacrificial gate structures 222 to form cavities, gaps, or recesses 234 in the source/drain regions. It is noted that FIG. 6 shows only one sacrificial gate structure 222 and the adjacent portion of fin 220 so that etching of the S/D region between the sacrificial gate structures 222 of FIG. 5 may be more clearly viewed. FIG. 7 is a cross sectional-view along line 6-6 in FIG. 6 but, like FIG. 5, FIG. 7 illustrates both sacrificial gate structures 222 and the fin 220 adjacent to both sacrificial gate structures 222.

The liner material layer and the dielectric material layer may remain on the sidewalls of the sacrificial gate structure 222 as the gate sidewall spacers 230, and on the sidewalls of the fins as the fin sidewall spacers 230. In some embodiments, the etching-back process may include a wet etch process, a dry etch process, a multiple-step etch process, and/or a combination thereof. The spacers 230 may have a thickness ranging from 5 to 20 nm.

As shown most clearly in FIG. 7, the stacked epitaxial layers 214 and 216 and an upper portion of substrate 100 forming fin 220 are etched down at the S/D regions. As a result, bottom gap surfaces 233 are formed in the fin 220. In some embodiments, the operation S914 forms the gaps 234 by a suitable etching process, such as a dry etching process, a wet etching process, or a combination thereof. As a result of the etching process, fin segments 235 of the upper portion of the fin 220 are defined and separated from one another by the gaps 234.

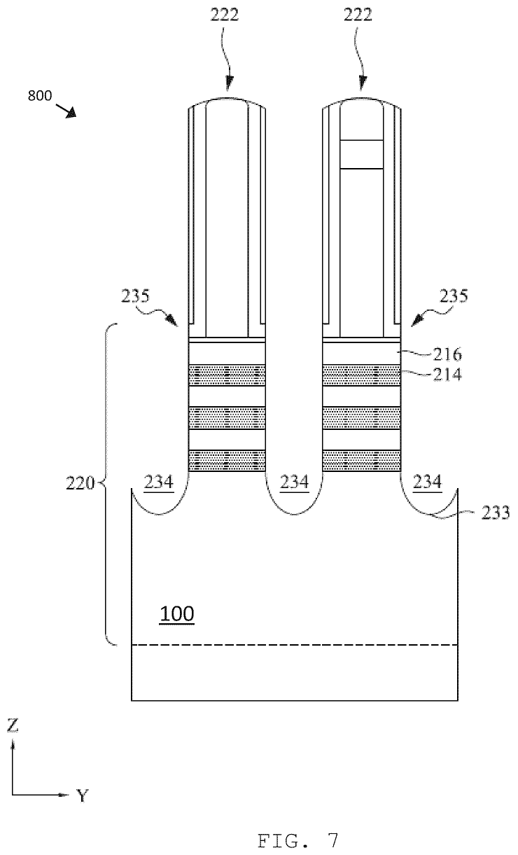

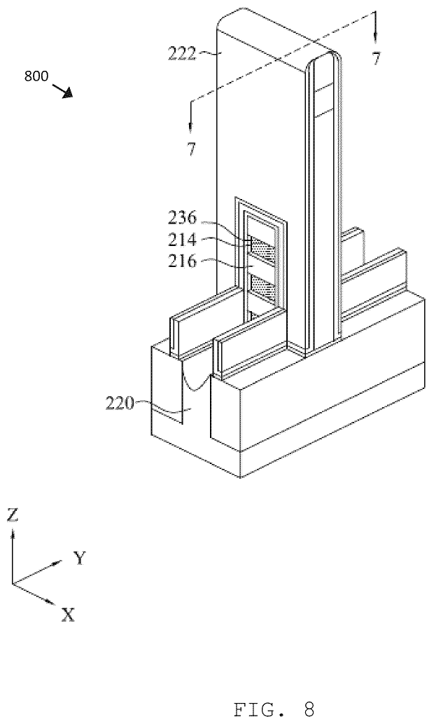

As shown in FIGS. 8 and 9, at operation S916, the method 900 (FIG. 1) etches the lateral ends of the epitaxial layers 214 in the Y-direction to recessed surfaces 336, thereby forming cavities 236. For example, operation S916 may etch the epitaxial layers 214 by a lateral distance of from 3 to 9.5 nanometers (nm). The amount of etching of the epitaxial layers 214 is in a range from 3 to 8 nm, such as from 4 to 7 nm, in some embodiments.

It is noted that FIG. 8, similar to FIG. 6, shows only one sacrificial gate structure 222 and the adjacent portion of fin 220 so that etching of the source/drain region between the sacrificial gate structures 222 may be viewed.

FIG. 9 is a cross-sectional view along line 7-7 of the structure in FIG. 8 but, like FIGS. 5 and 7, illustrates both sacrificial gate structures 222 and the adjacent fin 220.

The epitaxial layers 214 may be selectively etched by using a wet etchant such as, but not limited to, ammonium hydroxide (NH4OH), tetramethylammonium hydroxide (TMAH), ethylenediamine pyrocatechol (EDP), potassium hydroxide (KOH), HF, O3, H2O2, or HCl solutions. Alternatively, the operation S916 may first selectively oxidize lateral ends of the epitaxial layers 214 that are exposed in the gaps 234 to increase the etch selectivity between the epitaxial layers 214 and 216. In some examples, the oxidation process may be performed by exposing the GAA device 800 to a wet oxidation process, a dry oxidation process, or a combination thereof.

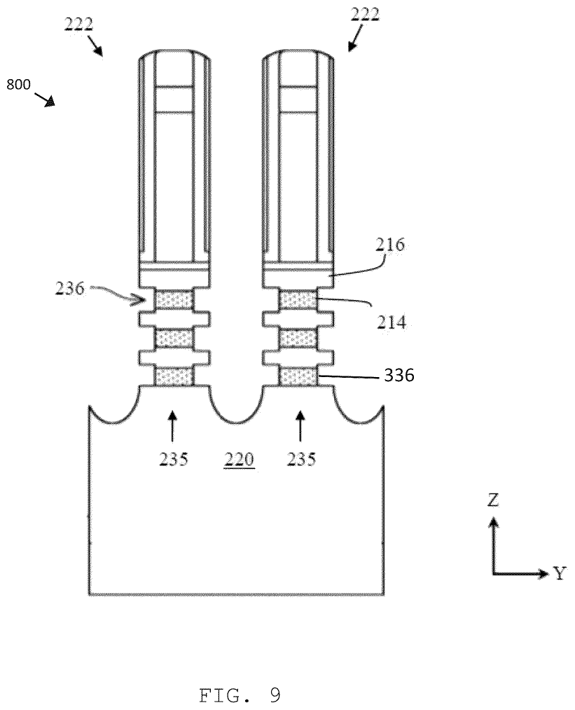

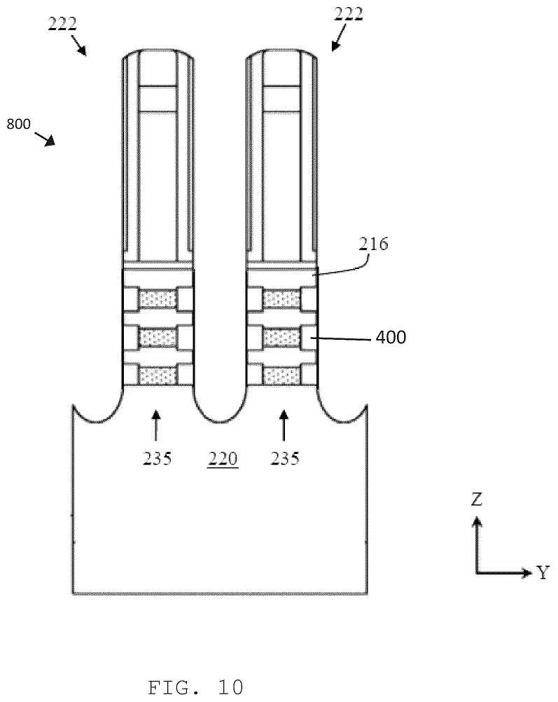

FIG. 10 is a cross-sectional view along line 7-7 of the structure in FIG. 8, at a successive stage of fabrication.

As shown in FIG. 10, method 900 (FIG. 1) may continue with operation S918 which forms inner spacers 400 in the cavities 236. For example, an inner spacer material layer may be deposited in the gaps 234 on the gap sidewalls, including on the lateral ends of the epitaxial layer 214, and on the ends and top and bottom surfaces of the epitaxial layers 216, and on the bottom gap surface 233. The inner spacer material layer may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer may be formed by ALD or any other suitable method. The inner spacer material layer may have a thickness ranging from 1 to 5 nm, for example from 1 to 4 nm, from 1 to 3 nm, or from 1 to 2 nm.

Operation S918 may further include trimming the inner spacer material layer. Removal of portions of the inner spacer material layer may be performed by an etching process, such as an anisotropic etching process, for example a dry etching process. In some embodiments, the dry etching process using an etchant including a fluorine-containing gas (e.g., SF₆, CF₄, CHF₃, CH₂F₂, and/or C₂F₆), a chlorine-containing gas (e.g., Cl₂), a bromine-containing gas (e.g., HBr and/or CHBR₃), oxygen-containing gas (e.g., O₂), a helium-containing gas (e.g., He), an argon-containing gas (e.g., Ar), other suitable gases, or combinations thereof. After this etching, the inner spacer material layer remains substantially within the cavities 236, because of small volumes of the cavities 236. Generally, plasma dry etching etches a layer in wide and flat areas faster than a layer in concave portions (e.g., holes, grooves, recesses and/or slits). Thus, the inner spacer material layer may remain inside the cavities 236.

FIG. 11 is a cross-sectional view along line 7-7 of the structure in FIG. 8, at a successive stage of fabrication.

As shown in FIG. 11, method 900 (FIG. 1) may continue with operation S920 which forms source/drain features 500 in the gaps 234. For example, operation S920 may include growing epitaxial material in the gaps 234 to form source/drain features 500. It is noted that the source/drain features 500 may be formed by successive formed layers. In exemplary embodiments, the source/drain features 500 are strained source/drain features 500. Also, the source/drain features 500 may be formed with layers selected for use in an NFET or PFET. In exemplary embodiments, the source/drain features 500 may include N-type epitaxial material source/drain features and P-type epitaxial material source/drain features. The epitaxial material may include one or more layers of Si, SiP, SiC and SiCP for an N-channel FET or Si, SiGe, Ge for a P-channel FET. For the P-channel FET, boron (B) may also be contained in the source/drain. The source/drain epitaxial layers may be formed by an epitaxial growth method using CVD, ALD, or molecular beam epitaxy (MBE).

FIG. 12 is a cross-sectional view along line 7-7 of the structure in FIG. 8, at a successive stage of fabrication.

As shown in FIG. 12, method 900 (FIG. 1) may continue, at operation S922, with capping the source/drain features 500 with dielectric. Specifically, a dielectric liner 440 may be formed over source/drain features 500 and along the sides of the sidewall spacers 230. Further, a dielectric 450 may be formed over the liner 440 over the source/drain features 500. Specifically, the gaps 234 are filled with dielectric 450. In exemplary embodiments, the dielectric 450 is a first interlayer dielectric layer (ILD). The dielectric 450 may be silicon oxide or other suitable dielectric material. In certain embodiments, the dielectric liner 440 is a dielectric, such as silicon nitride or another suitable material.

As shown in FIG. 12, the structure 800 may be planarized, such as by a chemical-mechanical planarization (CMP) process. Planarization may remove the mask 225 and uncover the sacrificial gate electrode 224.

FIG. 13 is a cross-sectional view along line 7-7 of the structure in FIG. 8, at a successive stage of fabrication. As shown in FIG. 13, method 900 (FIG. 1) may continue, at operation S924, with removing the sacrificial gate structures 222. As shown, the sacrificial gate electrode 224 is removed to form gate cavities 499 between sidewall spacers 230.

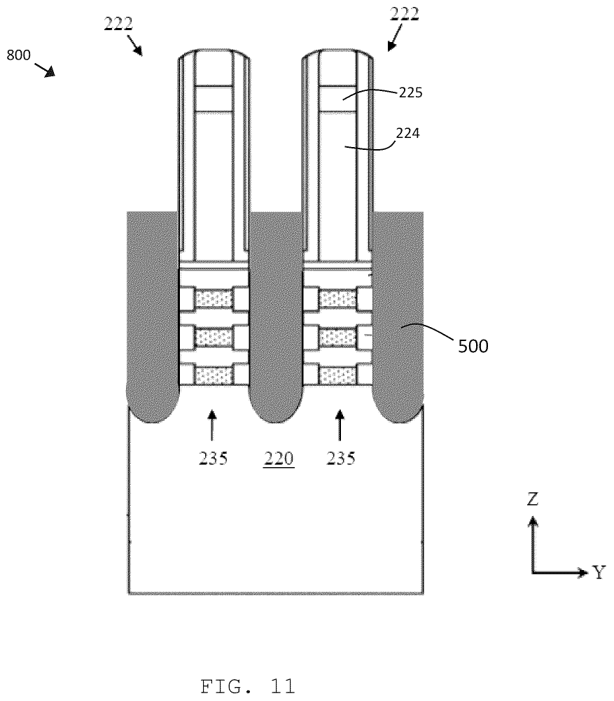

FIG. 14 is a cross-sectional view along line 7-7 of the structure in FIG. 8, at a successive stage of fabrication. As shown in FIG. 14, method 900 (FIG. 1) may continue, at operation S926, with removing the interposer layers 214 to define semiconductor layers 216 as nanosheet channel layers. Specifically, removing interposer layers 214 creates voids 215 around the semiconductor layers 216. In certain embodiments, operation S926 may include a wire-release process to form vertically-spaced nanosheets, in accordance with some embodiments. The wire release process step may also be referred to as a sheet release process step, a sheet formation process step, a nanosheet formation process step or a wire formation process step. In an embodiment the layers 214 may be removed using a wet etching process that selectively removes the material of the first layers (e.g., silicon germanium (SiGe)) without significantly removing the material of the second layers 216 (e.g., silicon (Si)). However, any suitable removal process may be utilized.

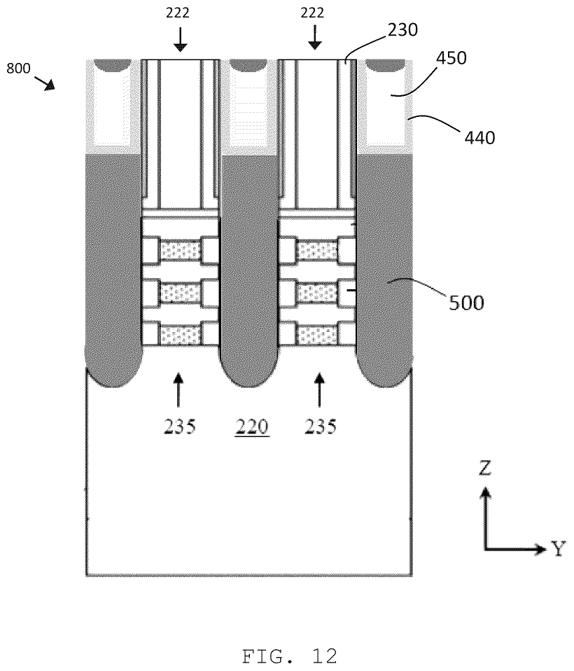

FIG. 15 is a cross-sectional view along line 7-7 of the structure in FIG. 8, at a successive stage of fabrication. Removal of the interposer layers 214 may lead to reduced thickness of the semiconductor layers 216. Therefore, method 900 (FIG. 1) may continue, at operation S928, with forming an additional capping layer 516 of semiconductor material, such as silicon, onto the semiconductor layers 216 as shown in FIG. 15.

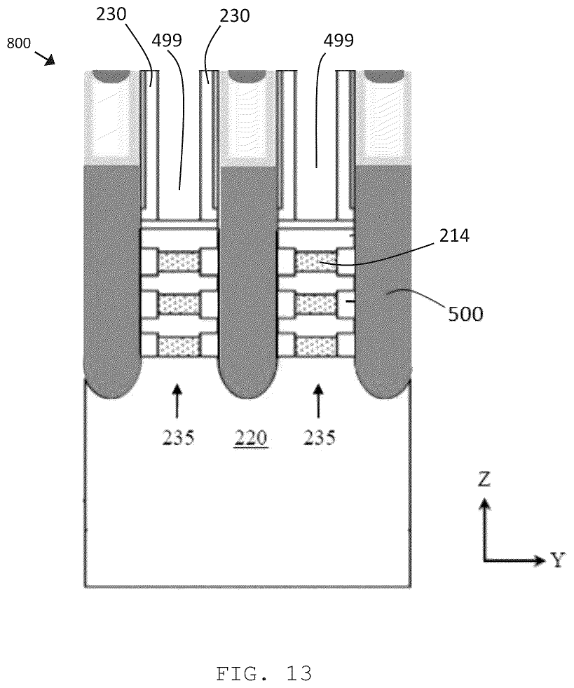

FIG. 16 is a cross-sectional view of the structure 800 of FIG. 15 along an X-cut, perpendicular to the cross-section of FIG. 15, along gate cavity 499. As shown in FIG. 16, capping layer 516 may be formed on all four sides of semiconductor layers 216.

FIG. 17 is a cross-sectional view along line 7-7 of the structure in FIG. 8, at a successive stage of fabrication. As shown in FIG. 17, method 900 (FIG. 1) may continue, at operation S930, with forming a device enhancement layer 518, such as an oxide layer. Layer 518 may be used to improve device performance of an NFET device.

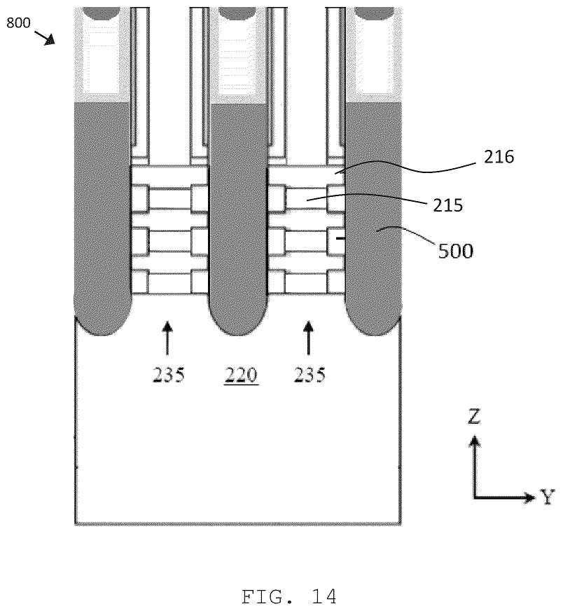

FIG. 18 is a cross-sectional view of the structure 800 of FIG. 17 along an X-cut, perpendicular to the cross-section of FIG. 17, along gate cavity 499. As shown in FIG. 18, layer 518 may be formed on all four sides of semiconductor layers 216.

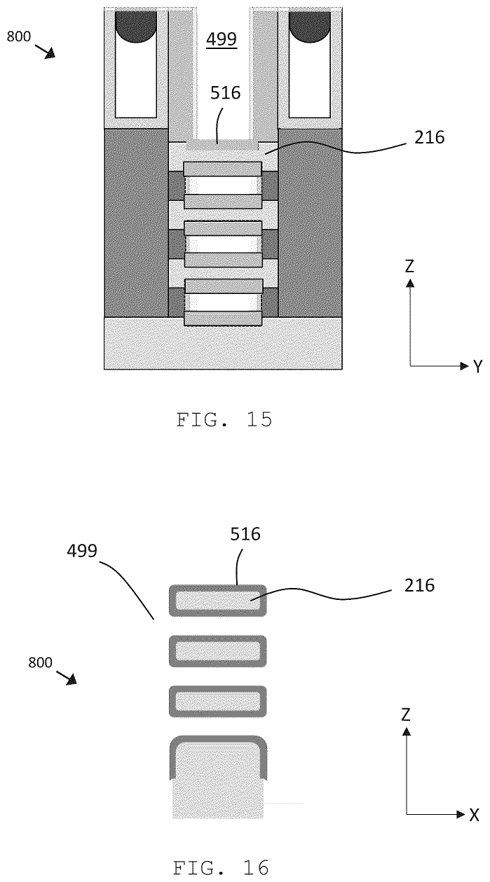

FIG. 19 is a cross-sectional view along line 7-7 of the structure in FIG. 8, at a successive stage of fabrication. As shown in FIG. 19, method 900 (FIG. 1) may continue, at operation S932, with forming a cover layer 530. Cover layer 530 may fill the voids 215. In certain embodiments, cover layer 530 is aluminum oxide.

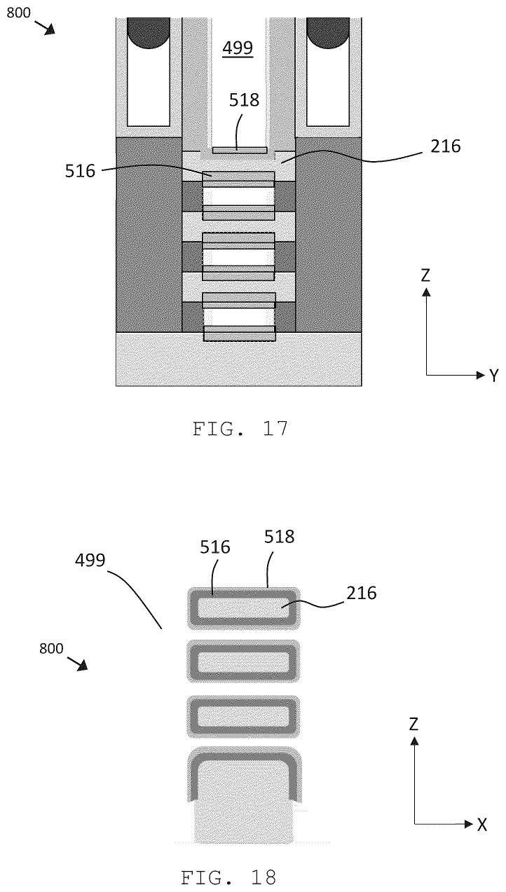

FIG. 20 is a cross-sectional view of the structure 800 of FIG. 19 along an X-cut, perpendicular to the cross-section of FIG. 17, along gate cavity 499.

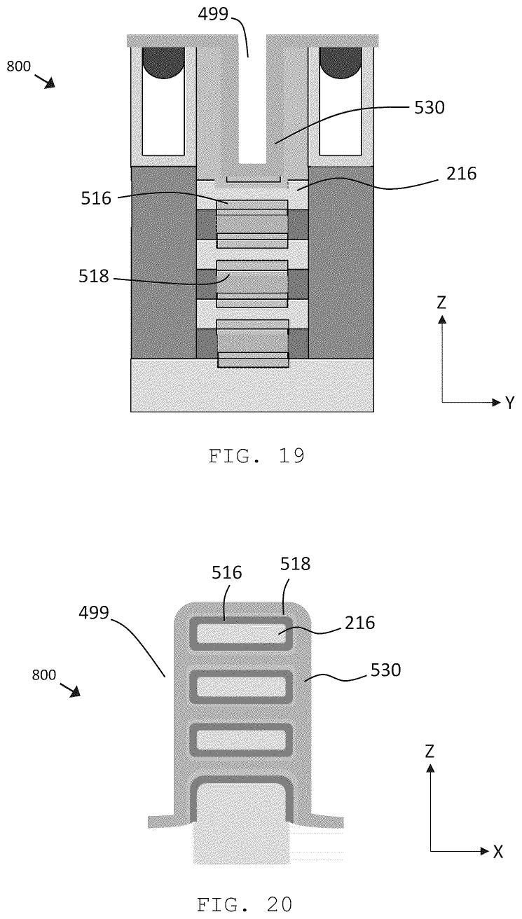

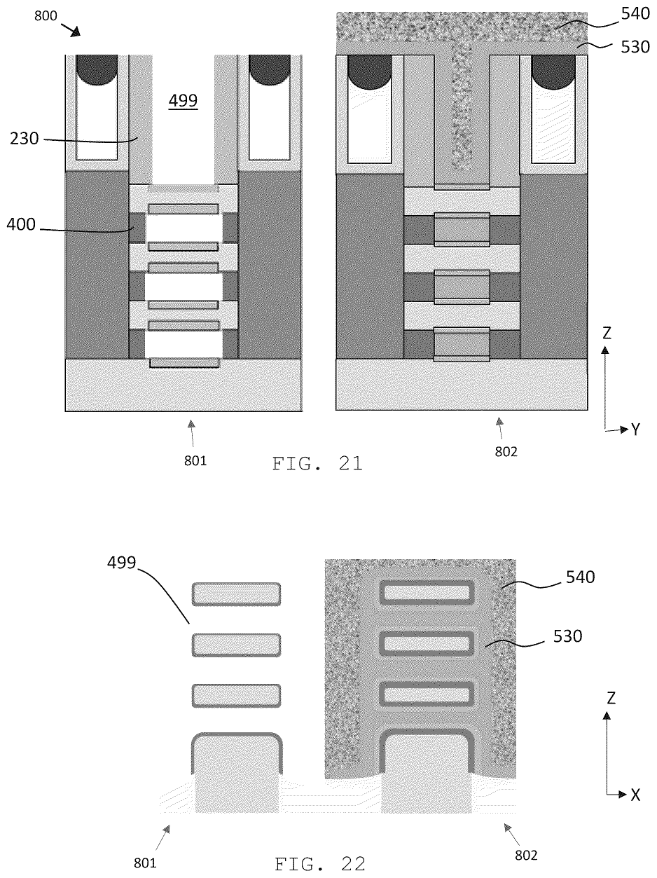

FIG. 21 is a cross-sectional view along line 7-7 of the structure in FIG. 8, at a successive stage of fabrication. FIG. 21 illustrates a first device region 801 and a second device region 802 where structures 800 may be simultaneously formed. For example, first device region 801 may include PFET devices 800, and second device region 802 may include NFET devices 800. As shown in FIG. 21, method 900 (FIG. 1) may continue, at operation S934, with forming a mask 540 over the second device region 802. FIG. 22 is a cross-sectional view of the structure 800 of FIG. 21 along an X-cut, perpendicular to the cross-section of FIG. 21, along gate cavity 499. Similar to FIG. 21, FIG. 22 illustrates a first device region 801 and a second device region 802.

Still referring to FIGS. 21 and 22, method 900 (FIG. 1) may continue, at operation S936, with trimming the inner spacers 400 in the first device region 801. As shown, the mask 540 prevents trimming of the inner spacers 400 in the second device region 802. Operation S936 includes removing the cover 530 in the first device region 801 and may also include trimming the sidewall spacers 230 and removing the layer 518 in the first device region 801.

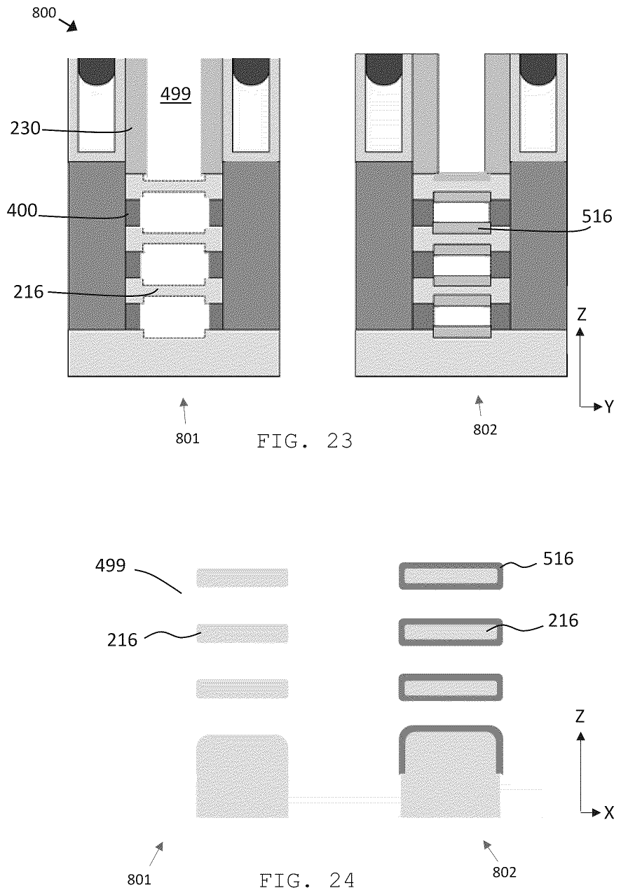

FIG. 23 is a cross-sectional view along line 7-7 of the structure in FIG. 8, at a successive stage of fabrication. As shown in FIG. 23, method 900 (FIG. 1) may continue, at operation S938, with removing the mask 540 from the second device region 802. FIG. 24 is a cross-sectional view of the structure 800 of FIG. 23 along an X-cut, perpendicular to the cross-section of FIG. 23, along gate cavity 499. Similar to FIG. 23, FIG. 24 illustrates a first device region 801 and a second device region 802. As shown, operation S938 may include removing the cover layer 530.

Still referring to FIGS. 23 and 24, method 900 (FIG. 1) may continue, at operation S940, with trimming the semiconductor layers 216. Operation S940 may include partially or completely removing the additional capping layer 516 from first device region 801.

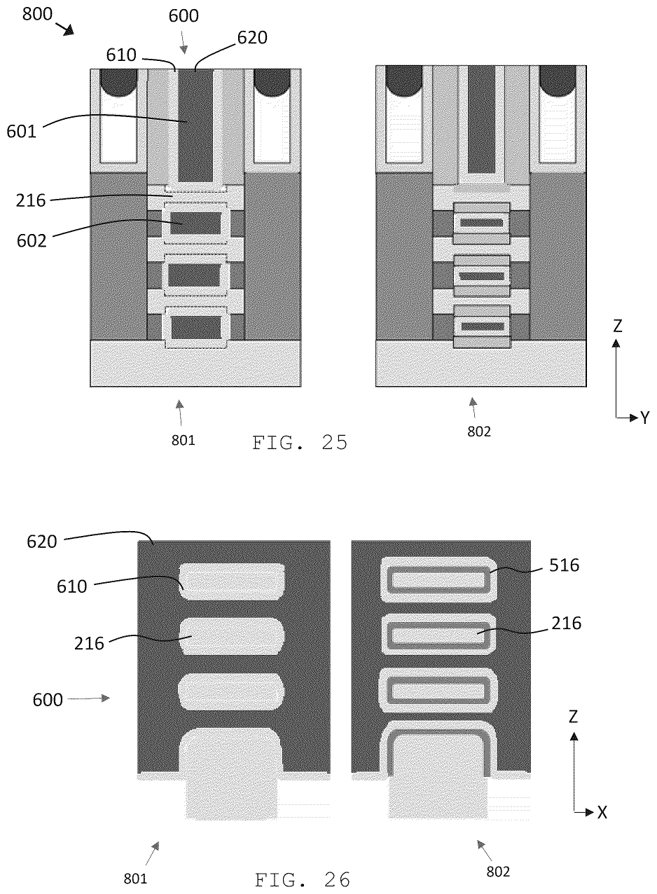

FIG. 25 is a cross-sectional view along line 7-7 of the structure in FIG. 8, at a successive stage of fabrication. As shown in FIG. 25, method 900 (FIG. 1) may continue, at operation S942, with forming a metal gate 600 in the gate cavity 499. FIG. 26 is a cross-sectional view of the structure 800 of FIG. 24 along an X-cut, perpendicular to the cross-section of FIG. 25, along metal gate 600. As shown in FIGS. 25 and 26, metal gate 600 may include a gate dielectric layer 610 and gate electrode material 620. An exemplary gate dielectric layer(s) 610 is deposited conformally in the gate cavities 499. The gate dielectric 610 may be formed on the semiconductor nanosheets 216, and the gate electrode material 620 may be formed on the gate dielectric layer(s) 610. Thus, each semiconductor nanosheet 216 is wrapped in gate dielectric 610 and surrounded by gate electrode material 620.

In accordance with some embodiments, the gate dielectric layer(s) 610 comprises silicon oxide, silicon nitride, or multilayers thereof. In some embodiments, the gate dielectric layer(s) 610 is a high-k dielectric material, and in these embodiments, the gate dielectric layer(s) 610 may have a k value greater than about 7.0, and may include a metal oxide or a silicate of Hf, Al, Zr, La, Mg, Ba, Ti, Pb, and combinations thereof. The formation methods of the gate dielectric layer(s) 610 may include Molecular-Beam Deposition (MBD), ALD, PECVD, and the like.

The gate electrode material 620 is deposited over the gate dielectric layer(s) 610 and fills the remaining portion of the gate cavity. The gate electrode material 620 may be a metal-containing material such as TiN, TaN, TaC, Co, Ru, Al, combinations thereof, or multi-layers thereof. For example, although a single gate electrode material is illustrated, any number of work function tuning layers may be deposited.

According to some embodiments, the gate electrode material 620 is formed using multiple layers, each layer deposited sequentially adjacent to each other using a highly conformal deposition process such as atomic layer deposition, although any suitable deposition process may be utilized. According to some embodiments, a capping layer, a barrier layer, an n-metal work function layer, a p-metal work function layer, and a fill material may be provided.

The capping layer may be formed adjacent to the gate dielectric 610 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as atomic layer deposition, chemical vapor deposition, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The n-metal work function layer may be formed adjacent to the barrier layer. In an embodiment the n-metal work function layer is a material such as W, Cu, AlCu, TiAlC, TiAlN, TiAl, Pt, Ti, TiN, Ta, TaN, Co, Ni, Ag, Al, TaAl, TaAlC, TaC, TaCN, TaSiN, Mn, Zr, other suitable n-type work function materials, or combinations thereof. For example, the first n-metal work function layer may be deposited utilizing an atomic layer deposition (ALD) process, CVD process, or the like. However, any suitable materials and processes may be utilized to form the n-metal work function layer.

The p-metal work function layer may be formed adjacent to the n-metal work function layer. In an embodiment, the first p-metal work function layer may be formed from a metallic material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-metal work function layer may be deposited using a deposition process such as atomic layer deposition, chemical vapor deposition, or the like, although any suitable deposition process may be used.

After the p-metal work function layer has been formed, the fill material is deposited to fill a remainder of the opening. In an embodiment the fill material may be a material such as tungsten, Al, Cu, AlCu, W, Ti, TiAlN, TiAl, Pt, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. However, any suitable material may be utilized.

As shown in FIGS. 25 and 26, the replacement metal gate process further includes removing excess portions of the gate dielectric layer(s) 610 and the gate electrode material 620 located over the top surface of the structure 800. For example, a planarization process, such as a CMP process, may be performed to remove the excess portions of the gate dielectric layer(s) 610 and the gate electrode material 620. The remaining portions of material of the gate dielectric layer(s) 610 and the gate electrode material 620 thus form the replacement gate structure 600 of the resulting device 800. The gate dielectric layer(s) 610 and gate electrode material 620 may be collectively referred to as a “gate,” a “gate stack,” or a “gate structure.” Each gate structure 600 may extend along sidewalls of a channel region of the fin structures.

As shown in FIG. 1, method 900 may continue at operation S944 with performing further processing. For example, dielectric layers and metallization layers may be deposited and etched to form interconnect structures. The further processing may include other back end of line (BEOL) processes such as passivation and packaging.

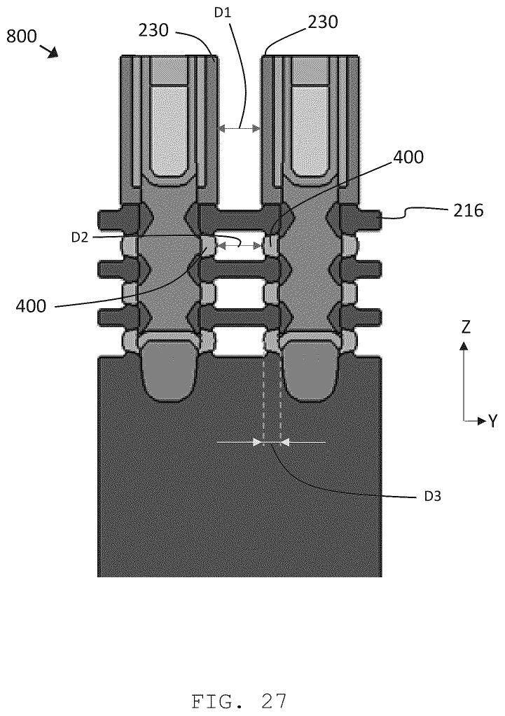

Referring now to FIG. 27, a Y-cut cross-section is provided. As shown, opposite sidewall spacers 230 are distanced from one another by a lateral, i.e., horizontal, distance or critical dimension D1. Further, opposite inner spacers 400 are distanced from one another by a lateral, i.e., horizontal, distance or critical dimension D2. Also, each inner spacer 400 extends from an inner surface to an outer surface to define a lateral, i.e., horizontal, thickness or critical dimension D3.

Cross-referencing FIGS. 25 and 27, it may be seen that the metal gate 600 includes an upper gate portion 601 located over the uppermost nanosheet channel layer 216. The upper gate portion 601 has a width between opposite sidewall spacers 230 equal to distance or critical dimension D1. Further, metal gate 600 includes a lower gate portion 602 located below the uppermost nanosheet channel layer 216. The lower gate portion 602 has a width between opposite inner spacers 400 equal to distance or critical dimension D2.

As described above, devices 800 in the first device region 801 are formed with thinner inner spacers 400 and thinner sidewall spacers 230 than devices 800 in the second device region 802. Thus, distances D1 and D2 are greater in the first device region 801 than in the second device region 802, while thickness D3 of the inner spacers 400 is smaller in the first device region 801 than in the second device region 802.

For example, in the first device region 801, distance D1 may be at least 15 nanometers (nm), such as at least 15.2 nm, at least 15.4 nm, at least 15.5 nm, at least 15.6 nm, at least 15.8 nm, at least 16.0 nm, at least 16.1 nm, at least 16.2 nm, at least 16.3 nm, at least 16.4 nm, or at least 16.5 nm, and at most 16.6 nm, such as at most 16.5 nm, at most 16.4 nm, at most 16.3 nm, at most 16.2 nm, at most 16.1 nm, at most 16.0 nm, at most 15.8 nm, at most 15.6 nm, or at most 15.5 nm.

In the first device region 801, distance D2 may be at least 16 nanometers (nm), such as at least 16.2 nm, at least 16.4 nm, at least 16.5 nm, at least 16.6 nm, at least 16.8 nm, at least 17.0 nm, at least 17.1 nm, at least 17.2 nm, at least 17.3 nm, at least 17.4 nm, or at least 17.5 nm, and at most 17.6 nm, such as at most 17.5 nm, at most 17.4 nm, at most 17.3 nm, at most 17.2 nm, at most 17.1 nm, at most 17.0 nm, at most 16.8 nm, at most 16.6 nm, or at most 16.5 nm.

In the first device region 801, thickness D3 may be at least 2.8 nanometers (nm), such as at least 3 nm, at least 3.1 nm, or at least 3.2 nm, at least 3.3 nm, at least 3.4 nm, at least 3.5 nm, at least 3.6 nm, at least 3.8 nm, or at least 4 nm, and at most 4.2 nm, such as at most 4 nm, at most 3.9 nm, at most 3.8 nm, at most 3.6 nm, at most 3.5 nm, at most 3.4 nm, at most 3.2 nm, at most 3.1 nm, or at most 3.0 nm.

In certain embodiments, in the first device region 801, distance D2 is at least 0.5 to 1 nm greater than distance D1. For example, in the first device region 801, distance D2 may be at least 0.5 nm, at least 0.6 nm, at least 0.7 nm, at least 0.8 nm, at least 0.9 nm, or at least 1 nm greater than distance D1. Further, in the first device region 801, distance D2 may be at most 1 nm, at most 0.9 nm, at most 0.8 nm, at most 0.7 nm, at most 0.6 nm, or at most 0.5 nm greater than distance D1.

In the second device region 802, distance D1 may be at least 15 nanometers (nm), such as at least 15.2 nm, at least 15.4 nm, at least 15.5 nm, at least 15.6 nm, at least 15.7 nm, at least 15.8 nm, at least 16.0 nm, at least 16.1 nm, at least 16.2 nm, at least 16.3 nm, at least 16.4 nm, or at least 16.5 nm, and at most 16.6 nm, such as at most 16.5 nm, at most 16.4 nm, at most 16.3 nm, at most 16.2 nm, at most 16.1 nm, at most 16.0 nm, at most 15.8 nm, at most 15.7 nm, at most 15.6 nm, or at most 15.5 nm.

In the second device region 802, distance D2 may be at least 15 nanometers (nm), such as at least 15.2 nm, at least 15.4 nm, at least 15.5 nm, at least 15.6 nm, at least 15.8 nm, at least 16.0 nm, at least 16.1 nm, at least 16.2 nm, at least 16.3 nm, at least 16.4 nm, or at least 16.5 nm, and at most 16.6 nm, such as at most 16.5 nm, at most 16.4 nm, at most 16.3 nm, at most 16.2 nm, at most 16.1 nm, at most 16.0 nm, at most 15.8 nm, at most 15.6 nm, or at most 15.5 nm.

In the second device region 802, thickness D3 may be at least 3.8 nanometers (nm), such as at least 4 nm, at least 4.1 nm, or at least 4.2 nm, at least 4.3 nm, at least 4.4 nm, at least 4.5 nm, at least 4.6 nm, at least 4.8 nm, or at least 5 nm, and at most 5.2 nm, such as at most 5 nm, at most 4.9 nm, at most 4.8 nm, at most 4.6 nm, at most 4.5 nm, at most 4.4 nm, at most 4.2 nm, at most 4.1 nm, or at most 4.0 nm.

In certain embodiments, in the second device region 801, distance D2 is no more than 0.5 nm greater than distance D1. For example, in the second device region 801, distance D2 may be no more than 0.4 nm, no more than 0.3 nm, no more than 0.2 nm, no more than 0.1 nm, or no more than 0.05 nm greater than distance D1. In the second device region 801, distance D2 may be at least 0.05 nm, such as at least 0.1 nm, at least 0.2 nm, at least 0.3 nm, at least 0.4 nm, or at least 0.5 nm greater than distance D2.

In certain embodiments, distance D1 in the first device region 801 is from 0.4 to 1.2 nm greater than distance D1 in the second device region 802. For example, distance D1 in the first device region 801 may be at least 0.4 nm, such as at least 0.5 nm, at least 0.6 nm, at least 0.7 nm, at least 0.8 nm, at least 0.9 nm, or at least 1 nm, greater than distance D1 in the second device region 802. Further, distance D1 in the first device region 801 may be at most 1.2 nm, such as at most 1.1 nm, at most 1.0 nm, at most 0.9 nm, at most 0.8 nm, at most 0.7 nm, at most 0.6 nm, at most 0.5 nm, or at most 0.4 nm, greater than distance D1 in the second device region 802.

In certain embodiments, a ratio of distance D1 in the first device region 801 to distance D1 in the second device region 802 is from 1.0:0.8 to 1.0:0.98, including all values and ranges therein.

In certain embodiments, distance D2 in the first device region 801 is from 0.4 to 1.2 nm greater than distance D2 in the second device region 802. For example, distance D2 in the first device region 801 may be at least 0.4 nm, such as at least 0.5 nm, at least 0.6 nm, at least 0.7 nm, at least 0.8 nm, at least 0.9 nm, or at least 1 nm, greater than distance D2 in the second device region 802. Further, distance D2 in the first device region 801 may be at most 1.2 nm, such as at most 1.1 nm, at most 1.0 nm, at most 0.9 nm, at most 0.8 nm, at most 0.7 nm, at most 0.6 nm, at most 0.5 nm, or at most 0.4 nm, greater than distance D2 in the second device region 802.

In certain embodiments, a ratio of distance D2 in the first device region 801 to distance D2 in the second device region 802 is from 1.0:0.8 to 1.0:0.98, including all values and ranges therein.

Distances D1 and D2 may differ between the first device region 801 and the second device region 802 due to trimming of the inner spacers 400 and sidewall spacers 230 in the first device region 801. Thus, the difference in distances D1 across regions 801 and 802, and the difference in distances D2 across regions 801 and 802, may be directly proportional to the thickness of the inner spacers.

The metal gate 600 in the first device region 801 may have a lateral width, which may be distance D1, distance D2, or an average across the metal gate 600 including distances D1 and D2; and the metal gate 600 in the second device region 802 may have a lateral width, which may be distance D1, distance D2, or an average across the metal gate 600 including distances D1 and D2. In certain embodiments, a ratio of the lateral width of the metal gate 600 in the first device region 801 to the lateral width of the metal gate 600 in the second device region 802 is from 1.1:1 to 10:1, including all values and ranges therein.

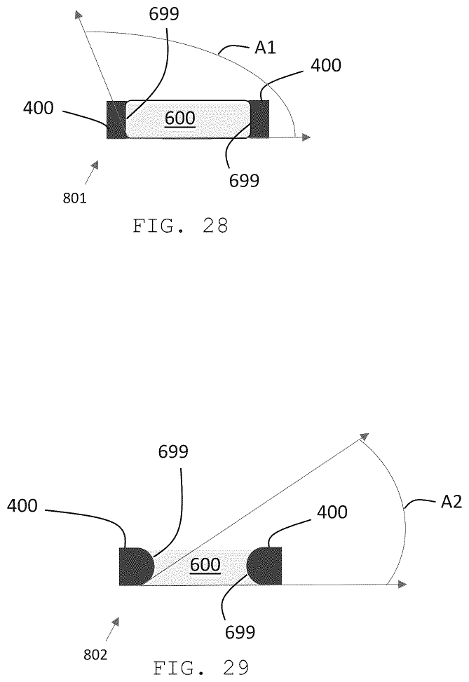

Referring to FIGS. 28 and 29, further features of embodiments herein are described. FIG. 28 illustrates the interfaces 699 between a metal gate 600 and surrounding inner spacers 400 in a first device region 801. FIG. 29 illustrates the interfaces 699 between a metal gate 600 and surrounding inner spacers 400 in a second device region 802.

As shown in FIG. 28, the metal gate has convex vertical profiles at the interface 699 with the inner spacers 400 in the first device region 801. In other words, a central height portion of the metal gate 600, between the bottom and top surfaces of the metal gate 600, has the maximum critical dimension, and the top and bottom surfaces has a smaller critical dimension as shown in FIG. 28. Further, the interface 699 is formed with a bottom angle A1 of from 95 to 110 degrees.

As shown in FIG. 29, the metal gate has concave vertical profiles at the interface 699 with the inner spacers 400 in the second device region 802. In other words, a central height portion of the metal gate 600, between the bottom and top surfaces of the metal gate 600, has a smaller critical dimension, and the top and bottom surfaces have the maximum critical dimension as shown in FIG. 29. Further, the interface 699 is formed with a bottom angle A2 of from 60 to 70 degrees.

In certain embodiments the angle difference of (A1−A2) is from 35 to 40 degrees.

In an embodiment, a method includes, in a first device region and in a second device region: forming a semiconductor layer over an interposer layer; etching a trench through the semiconductor layer and interposer layer; forming an inner spacer laterally adjacent to the trench; and removing the interposer layer. The method further includes covering the second device region with a mask; and recessing the inner spacer laterally in the first device region.

In certain embodiments, the method further includes, after recessing the inner spacer laterally, removing the mask from the second device region.

In certain embodiments, the method further includes, in the first device region and in the second device region, forming a metal gate around the semiconductor layer, wherein the metal gate in the first device region has a first lateral width, and wherein the metal gate in the second device region has a second lateral width less than the first lateral width.

In certain embodiments of the method, a ratio of the first lateral width to the second lateral width is from 1.1:1 to 10:1.

In certain embodiments of the method, in the first device region, the metal gate has a convex vertical profile at an interface with the inner spacer.

In certain embodiments of the method, in the second device region, the metal gate has a concave vertical profile at an interface with the inner spacer.

In certain embodiments of the method, forming the inner spacer laterally adjacent to the trench includes etching a sidewall of the interposer layer to form a gap; and forming the inner spacer in the gap.

In certain embodiments, the method further includes, after forming the inner spacer laterally adjacent to the trench, forming a source/drain feature in the trench in the first device region and in the second device region.

In certain embodiments, the method further includes forming a sacrificial structure over the semiconductor layer and interposer layer before etching the trench through the semiconductor layer and interposer layer in the first device region and in the second device region; forming a dielectric layer over the source/drain feature in the first device region and in the second device region; and removing the sacrificial structure to form a gate cavity adjacent to the dielectric layer before removing the interposer layer.

In another embodiment, a method includes forming a stack of a semiconductor layer and an interposer layer; forming a sacrificial gate structure over the stack, wherein the sacrificial structure lies over a covered portion of the stack that lies between uncovered portions of the stack; removing the uncovered portions of the stack to form trenches, wherein sidewalls of the semiconductor layer and interposer layer define the trenches; forming inner spacers laterally adjacent to the sidewalls of the interposer layer; removing the sacrificial gate structure to form an upper portion of a gate cavity; removing the interposer layer to form a lower portion of the gate cavity; recessing the inner spacers laterally; and forming a metal gate in the gate cavity.

In certain embodiments of the method, the metal gate in the upper portion of the gate cavity has a first maximum critical dimension, the metal gate in the lower portion of the gate cavity has a second maximum critical dimension, and the second maximum critical dimension is greater than the first maximum critical dimension.

In certain embodiments of the method, a ratio of the first maximum critical dimension to the second maximum critical dimension is from 1:0.8 to 1:0.98.

In certain embodiments of the method, the inner spacers include a first inner spacer and a second inner spacer; and each inner spacer has a third maximum critical dimension of from 3 to 4 nm.

In certain embodiments of the method, the inner spacers include a first inner spacer and a second inner spacer; the metal gate in the lower portion of the gate cavity extends from a first interface with the first inner spacer to a second interface with the second inner spacer; and the metal gate has a convex vertical profile at the first interface and at the second interface.

In another embodiment, a semiconductor structure includes a first gate-all-around (GAA) device in a first region, including a first metal gate including a first lower portion below a first semiconductor nanosheet and extending between opposite first inner spacers for a first maximum critical dimension; and a second gate-all-around (GAA) device in a second region, including a second metal gate including a second lower portion below a second semiconductor nanosheet and extending between opposite second inner spacers for a second maximum critical dimension less than the first maximum critical dimension.

In certain embodiments of the semiconductor structure, the second maximum critical dimension is at least 0.5 nm less than the first maximum critical dimension.

In certain embodiments of the semiconductor structure, a ratio of the first maximum critical dimension to the second maximum critical dimension is from 1:0.8 to 1:0.98.

In certain embodiments of the semiconductor structure, the first metal gate includes a first upper portion above the first semiconductor nanosheet and extending between opposite first sidewalls for a first maximum upper critical dimension; and the second metal gate includes a second upper portion above the second semiconductor nanosheet and extending between opposite second sidewalls for a second maximum upper critical dimension less than the first maximum upper critical dimension.

In certain embodiments of the semiconductor structure, a ratio of the first maximum upper critical dimension to the second maximum upper critical dimension is from 1:0.8 to 1:0.98.

In certain embodiments of the semiconductor structure, each first inner spacer has a first spacer maximum critical dimension; and each second inner spacer has a second spacer maximum critical dimension greater than the first spacer maximum critical dimension.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
in a first device region and in a second device region:
forming a semiconductor layer over an interposer layer;
etching a trench through the semiconductor layer and interposer layer;
forming an inner spacer laterally adjacent to the trench; and
removing the interposer layer;
covering the second device region with a mask; and
recessing the inner spacer laterally in the first device region.

2. The method of claim 1, further comprising, after recessing the inner spacer laterally, removing the mask from the second device region.

3. The method of claim 1, further comprising, in the first device region and in the second device region, forming a metal gate around the semiconductor layer, wherein the metal gate in the first device region has a first lateral width, and wherein the metal gate in the second device region has a second lateral width less than the first lateral width.

4. The method of claim 3, wherein a ratio of the first lateral width to the second lateral width is from 1.1:1 to 10:1.

5. The method of claim 4, wherein in the first device region, the metal gate has a convex vertical profile at an interface with the inner spacer.

6. The method of claim 5, wherein in the second device region, the metal gate has a concave vertical profile at an interface with the inner spacer.

7. The method of claim 1, wherein forming the inner spacer laterally adjacent to the trench comprises:
etching a sidewall of the interposer layer to form a gap; and
forming the inner spacer in the gap.

8. The method of claim 7, further comprising:
after forming the inner spacer laterally adjacent to the trench, forming a source/drain feature in the trench in the first device region and in the second device region.

9. The method of claim 8, further comprising:
forming a sacrificial structure over the semiconductor layer and interposer layer before etching the trench through the semiconductor layer and interposer layer in the first device region and in the second device region;
forming a dielectric layer over the source/drain feature in the first device region and in the second device region; and
removing the sacrificial structure to form a gate cavity adjacent to the dielectric layer before removing the interposer layer.

10. A method comprising:
forming a stack of a semiconductor layer and an interposer layer;
forming a sacrificial gate structure over the stack, wherein the sacrificial structure lies over a covered portion of the stack that lies between uncovered portions of the stack;
removing the uncovered portions of the stack to form trenches, wherein sidewalls of the semiconductor layer and interposer layer define the trenches;
forming inner spacers laterally adjacent to the sidewalls of the interposer layer;
removing the sacrificial gate structure to form an upper portion of a gate cavity;
removing the interposer layer to form a lower portion of the gate cavity;
recessing the inner spacers laterally; and
forming a metal gate in the gate cavity.

11. The method of claim 10, wherein:
the metal gate in the upper portion of the gate cavity has a first maximum critical dimension;
the metal gate in the lower portion of the gate cavity has a second maximum critical dimension; and
the second maximum critical dimension is less than the first maximum critical dimension.

12. The method of claim 11, wherein a ratio of the first maximum critical dimension to the second maximum critical dimension is from 1:0.8 to 1:0.98.

13. The method of claim 12, wherein:
the inner spacers include a first inner spacer and a second inner spacer; and
each inner spacer has a third maximum critical dimension of from 3 to 4 nm.

14. The method of claim 10, wherein:
the inner spacers include a first inner spacer and a second inner spacer;
the metal gate in the lower portion of the gate cavity extends from a first interface with the first inner spacer to a second interface with the second inner spacer; and
the metal gate has a convex vertical profile at the first interface and at the second interface.

15. A semiconductor structure comprising:
a first gate-all-around (GAA) device in a first region, comprising a first metal gate including a first lower portion below a first semiconductor nanosheet and extending between opposite first inner spacers for a first maximum critical dimension; and
a second gate-all-around (GAA) device in a second region, comprising a second metal gate including a second lower portion below a second semiconductor nanosheet and extending between opposite second inner spacers for a second maximum critical dimension less than the first maximum critical dimension.

16. The semiconductor structure of claim 15, wherein the second maximum critical dimension is at least 0.5 nm less than the first maximum critical dimension.

17. The semiconductor structure of claim 15, wherein a ratio of the first maximum critical dimension to the second maximum critical dimension is from 1:0.8 to 1:0.98.

18. The semiconductor structure of claim 15, wherein:
the first metal gate includes a first upper portion above the first semiconductor nanosheet and extending between opposite first sidewalls for a first maximum upper critical dimension; and
the second metal gate includes a second upper portion above the second semiconductor nanosheet and extending between opposite second sidewalls for a second maximum upper critical dimension less than the first maximum upper critical dimension.

19. The semiconductor structure of claim 18, wherein a ratio of the first maximum upper critical dimension to the second maximum upper critical dimension is from 1:0.8 to 1:0.98.

20. The semiconductor structure of claim 15, wherein:
each first inner spacer has a first spacer maximum critical dimension; and
each second inner spacer has a second spacer maximum critical dimension greater than the first spacer maximum critical dimension.
